(19) United States
(12) Patent Application Publication
(10) Pub. No.: US 2004/0101636 A1
(43) Pub. Date: May 27, 2004

(54) Method for producing a coated synthetic body

(76) Inventors: Markus Kuhr, Wollstein (DE); Detlef Woff, Mainz (DE); Marten Walther, Engelstadt (DE); Stephan Behle, Hahnheim (DE); Stefan Bauer, Baum (DE); Lutz Klippe, Wiesbaden (DE); Christoph Moelle, Bad Gandersheim (DE); Lars Bewig, Bad Gandersheim (DE); Frank Koppe, Bad Gandersheim (DE); Thomas Kupper, Bad Gandersheim (DE); Wolfram Maring, Hairsburg (DE); Jochen Heinz, Kiel (DE)

Correspondence Address: LERNER AND GREENBERG, PA, P O BOX 2480, HOLLYWOOD, FL, 33022-2480, US

(21) Appl. No.: 10/473,261

(22) PCT Filed: Mar. 28, 2002
(86) PCT No.: PCT/EP02/03528

(30) Foreign Application Priority Data
Mar. 29, 2001 (EP) 01107967.0
Mar. 29, 2001 (EP) 01107966.2
Dec. 21, 2001 (DE) 101 63 625.3

(51) Int. Cl. C23C 16/00; H05H 1/24

(52) U.S. Cl. 427/569; 427/255.28; 118/723 MW

(57) ABSTRACT

The invention relates to coating a plastic substrate for producing a coated body, to a device for carrying out such a method, and to the use thereof.

### DESCRIPTION

The invention relates to coating a plastic substrate for producing a coated body, to a device for carrying out such a method, and to the use thereof.

This relates to bodies of any type and shape. Consideration is given, in particular, to curved bodies or slightly curved bodies, for example spectacle lenses. Also considered are flat or approximately flat bodies such as display cover plates, for example in mobile radio units, fixed telephone stations etc. The plastic mentioned is, for example, polymethyl methacrylate (PMMA) and its derivatives, or plastics essentially identical thereto. PMMA has proved itself splendidly in the various fields of application and is cost effective.

The coating is a multiple coating. The individual layers are optical functional layers such as, for example, an antireflection layer or an antireflection layer system consisting of a plurality of individual layers, but also layers with particular mechanical properties such as, for example, a hydrophobic cover layer, the so-called cleaning layer that can easily be cleaned mechanically, or an anti-scratching layer. A so-called adhesion promoter layer, called an “intermediate layer” here very generally, is generally applied between the functional layers and the substrate. Said intermediate layer is of decisive importance for the usability of the overall product. Specifically, it is responsible for the adhesion of the entire layer package on the substrate. The intermediate layer can be a single homogeneous layer. It can also be a multiple layer. In this case, the individual layers form a gradient starting from a layer that directly follows the substrate and is substantially identical or similar to said substrate as organic compound, up to a layer that is near the next subsequent functional layer and that is essentially identical or similar to the latter as inorganic compound.

Coated optical components made from organic polymers are increasingly replacing components made from glass for various applications, since they offer a range of advantages. Polymers can be manufactured in one operation, and therefore without expensive secondary finishing, with a high surface quality. Mass production is therefore comparatively cost effective. In addition, polymers offer better possibilities for shaping, miniaturization and also for microstructuring of surfaces. The lower weight of polymers is advantageous for specific applications.

Polymeric component parts with interference coating for optical applications are presently coated by ion-assisted vapor deposition. The polymers can be coated with an antireflection layer system in this case for example. By comparison with the established coating processes for glass substrates, a few special features need to be observed when coating polymers. Since polymers have substantial differences in thermal and mechanical properties from those both of glass as substrate material and of the common dielectric layer materials such as TiO₂ and SiO₂, high application-specific requirements are placed on the substrate/layer adhesion and the long term stability of the layer system. The overall process from material selection via the production of the substrates up to the actual coating method must be designed with regard to these requirements. High thermal alternating loads such as occur, for example, in optical systems of very high light power or energy density, frequently exceed even the load limits for the layer adhesion and the life of the coated optical polymers. In addition, polymers are temperaturesensitive and may therefore be exposed only to low thermal loading during coating.

Numerous methods are known for producing objects of the said type, that is to say plastic substrates on which layers are located.

WO 01/07678 A1 relates to the deposition of purely inorganic layers, in particular to inorganic substrates. The problem of the adhesion of inorganic layers on plastic, that is to say organic substrates, is not examined in this document, nor is a solution to this disclosed.

DE 197 40 806 A1 describes microtitration plates made from plastic which, for the purpose of increasing the chemical resistance of the microtitration plate to organic solvents, are provided with a layer made from SiOₓC_{y}H_{z} and/or TiOₓC_{y}H_{z}. This document does not, however, relate either to optical layers or to anti-scratching layers on plastic substrates.

U.S. Pat. No. 5,900,285 relates to barrier coatings on polycarbonate, in particular. However, no optical coatings, in particular not ones on PMMA, are described.

EP 0 752 483 A1 and DE 195 23 444 A1 relate to coating metal and plastic surfaces by means of a PACVD method (PACVD plasma-assisted CVD method). The coating conditions applied are relatively drastic, however, and so damage to the substrate occurs, in particular given the required coating times of one hour and, in particular, on PMMA.

In accordance with EP 0 285 870, the substrate is heated to 100° C. or more for better coating. Such exposure of the substrate to heat is not desirable, in particular in the case of PMMA, and leads to a damaged substrate surface. Furthermore, the adhesive layer is not applied by a CVD method in accordance with this document.

DE 197 03 538 A1 describes a method for modifying surfaces of PMMA substrates. The substrate surface is provided with a protective layer in this case. The aim thereby is to facilitate the achievement of improved adhesion for functional layers that are to be applied subsequently. The application of the said protective layer constitutes an additional method step and therefore signifies additional complication and costs.

Further methods for applying thin layers to plastic substrates are described in DE 34 13 019 A1, EP 0 422 323 A1, DE 40 04 116 A1 and others. This also involves, inter alia, the adhesion of the layer that is applied to the substrate, specifically by means of the CVD or PECVD method. DE 100 10 766 exhibits and describes a method and a device for coating substrates, in particular curved ones, for example spectacle lenses.

The methods previously applied have not proved satisfactory. The requisite adhesion has not been achieved in particular, in this case. Rather, in the case of objects produced in this way there is the risk of the mentioned intermediate layer, and thus the entire layer package, being loosened. This can cause the object to be virtually unusable.

It is therefore the object of the invention to specify a method and a device with the aid of which method and/or device a plastic substrate, in particular a PMMA-comprising substrate can be coated with an intermediate layer, the so-called adhesion promoter layer, as well as at least functional layer. The intermediate layer is intended to adhere reliably on the substrate, and the individual layers likewise to adhere to one another such that any detachment is excluded. The method and device are to be cost effective. The aim is to facilitate the production of climate-proof and/or UV-proof products. Moreover, the invention is also to specify an appropriate product that is distinguished by a reliable adhesion between the substrate, intermediate layer and functional layer(s), that can be produced cost effectively, and that is, if appropriate, climate-proof and UV-proof.

A further object of the present invention consists in provided a transparent coated substrate that, in addition to the optical functions, satisfies the stringent requirements placed on stability and layer adhesion, and to provide an economic and environmentally friendly method for producing transparent coated substrates.

These objects are achieved by means of the embodiments of the present invention that are described in the claims.

In particular, the present invention relates to a method for coating a plastic substrate having at least one functional layer and at least one intermediate layer located between the functional layer(s) and the substrate, comprising the following method steps:

(1) applying the intermediate layer to the substrate by means of a PECVD method, the application being performed in conjunction with minimum energy loading of the substrate, and

(2) applying at least one functional layer.

According to the invention, the intermediate layer and, preferably, also at least one functional layer are applied by means of a so-called PECVD method (PEVCD “plasma enhanced chemical vapor deposition”), that is to say a plasma-assisted CVD method. It is particularly preferred for all the layers to be applied by the same method.

The inventors realized, in particular, that with the previously applied PECVD methods of applying layers to a substrate the boundary surface or the interface between the applied layer and the substrate is disturbed by the energy loading associated therewith, or has its structure destroyed. This is attended by a reduction in the adhesion between the substrate and bordering layer. The inventors consequently realized that the energy loading associated with the plasma discharge needed to be minimized in order to enhance the adhesion. This involves both the magnitude of the applied energy and the way in which it is applied. The admissible limiting value of the loading for the purpose of achieving adhesion that suffices in practice can be determined by experiment.

Two essential ways of applying these findings are as follows:

Firstly, the energy loading can be kept within limits in such a way that the plasma is applied in a pulsed way, that is to say periodically, for example, and thus in intervals which always remain the same, or intermittently, the intervals not requiring to be constant. This method was introduced by the applicant and denoted as “PICVD” method (PICVD “plasma impulse chemical vapor deposition”). The pulsed mode of operation that has been mentioned is essential in this case. The energy loading of the substrate is thereby reduced. At the same time, the anchoring effect consequent on the plasma treatment is retained.

In such a PICVD method, the total duration of the plasma action should be at least 1/1 000 of the action-free time interval between two plasma impulses and should be at most equal to said time interval. In accordance with this embodiment of the method according to the invention, it is preferred, furthermore, that the action impulse of the plasma application last between 0.1 and 10 ms, more preferably between 0.5 and 5 ms.

Secondly, it is possible to implement the said basic idea of the invention, that is to say a reduction in energy loading of the interface between the substrate and applied layer, in particular also to the application of a high coating rate in the PECVD method step. This means that the layer can be grown on or up quickly, so that as much layer substance is applied in the shortest possible time interval. Preferably, the layer thickness applied per time unit, that is to say the coating rate, during the plasma action is more than 10 nm/min, more preferably more than 100 nm/min. Such a high coating rate should be selected, in particular, at the start of the coating of the substrate.

A combination of the two named ways is also possible. Thus, the pulsed mode of procedure can be combined with a high coating rate. Particularly kind reaction conditions be achieved by this measure.

According to the invention, a plastic substrate is coated, a plastic being understood as an organic polymeric compound. Consideration is given as such plastics to high performance plastics which are stable as far as possible up to a temperature of 100° C. or more. The method according to the invention has a favorable effect even for yet more heatsensitive plastics, since the substrate temperature is kept low during the coating operation, preferably at room temperature or at most 40° C.

It is preferred to coat transparent plastics. Plastics such as polymethyl methacrylate (PMMA), polyethylene terephthalate (PET), polycarbonate (PC), polyetherimide, cycloolefin polymers (COP), cycloolefin copolymers (COC) or mixtures or blends thereof may be mentioned by way of example.

The following commercially available polymers may be used in this case: polymethyl methacrylate (Plexiglas®), polycarbonate (Makrolon®), cycloolefin copolymers (Topas® or Zeonex®), polyetherimide (Ultem®) or polyether sulfone (Ultrason®).

It is possible, in particular, for the first time with the aid of the invention to coat a layer package on PMMA, which is difficult to coat, and the derivatives thereof or essentially identical plastics, for example polymers and copolymers of acrylic acid and methacrylic acid, and derivatives thereof including polyacrylonitrile or essentially identical plastics in conjunction with a very high reliability of adhesion. It is therefore possible for thin high-grade layers to bind reliably to the substrate in the micrometer or submicrometer range.

A preferred refinement of the invention is a transparent coated substrate, at least one layer of at least one metal oxide being applied to the substrate by means of CVD. The metal oxides are preferably oxides of the metals Si, Ti, Ta or Nb. Although Si is generally denoted as a semimetal, it is assigned to the group of metals in accordance with this invention because it behaves like a metal compound in a method in accordance with the present invention. It is particularly preferred for the metal oxides to be SiO₂, TiO₂, Ta₂O₅ or Nb₂O₅. Very good results are obtained for layer adhesion with these metal oxides.

At least one silicon-containing layer is always applied as a rule. Precursor compounds for organosilicon compounds suitable for a silicon-containing layer include silanes, siloxanes and silazanes, and are, for example, one of the following compounds: methylsilane, dimethylsilane, trimethylsilane, diethylsilane, propysilane, phenylsilane, hexamethyldisilane, 1,1,2,2-tetramethyldisilane, bis(trimethylsilyl)methane, bis(dimethylsilyl)methane, hexamethyldisiloxane, vinyltrimethoxysilane, vinyltriethoxysilane, ethylmethoxysilane, ethyltrimethoxysilane, divenyltetramethyldisiloxane, divinylhexamethyltrisiloxane and trivinylpentamethyltrisiloxane, 1,1,2,2-tetramethyldisiloxane, hexamethyldisiloxane, vinyltrimethylsilane, methyltrimethoxysilane, vinyltrimethoxysilane and hexamethyldisilazane. Preferred silicon compounds are tetramethyldisiloxane, hexamethyldisiloxane (HMDSO), hexamethyldisilazane, tetramethylsilazane, dimethoxydimethylsilane, methyltrimethoxysilane, tetramethoxysilane, methyltriethoxysilane, diethoxydimethylsilane, methyltriethoxysilane, triethoxyvinylsilane, tetraethoxysilane, dimethoxymethylphenylsilane, phenyltrimethoxysilane, 3-glycidoxypropyltrimethoxysilane, diethoxymethylphenylsilane, tris(2-methoxyethoxy)vinylsilane, phenyltriethoxysilane and dimethoxydiphenylsilane.

According to the invention, the so-called “intermediate layer”, which serves as adhesion promoter layer, is firstly applied to the substrate. Said adhesion promoter layer is of very decisive importance for the usefulness of the overall product, since it ensures the entire layer system adheres on the substrate. The intermediate layer can be a single homogeneous layer. It can also be a multiply layer. In the case of such a multiply layer, the individual layers can form a gradient starting from a layer directly following the substrate, which is essentially identical or similar to the latter as organic compound, up to a layer that is followed by the first functional layer and which is essentially identical to the latter as inorganic compound. The term “organic compound” is understood in this case to be an essentially organic compound, that is to say one rich in carbon and/or hydrocarbons such as for example, an organic polymeric compound. By contrast thereto, an “inorganic compound” is an inorganic, low-carbon compound such as a metal oxide for example. The intermediate layer preferably has a thickness of at least 10 nm, preferably of least 200 nm or else 1 000 nm.

The layer can be produced with any desired thickness, but thicknesses of more than 2 000 nm are no longer economic because of their lengthened production time.

According to the invention, in addition to the intermediate layer the substrate is coated with at least one functional layer. At least two functional layers are preferably applied so that a multiple layer system results.

The functional layers can be applied, for example, as so-called optical layers, that is to say layers with particular optical properties such as a specific transparency, a specific refractive index, a specific color etc. for example an antireflection layer or an antireflection layer system consisting of a plurality of individual layers.

Furthermore, functional layers can be layers with particular mechanical properties such as, for example, an anti-scratching layer. Furthermore, a hydrophobic cover layer, a so-called cleaning layer, which can easily be cleaned mechanically, can be applied. In addition, such functional layers can lend the substrate barrier properties, a chemical, UV- or climate-proofness.

Such functional layers each have, for example, a layer thickness of 0.1 μm to 5 μm. Depending on use, however it is also possible to apply layers in the nm range.

The method and the device for carrying it out are particularly cost effective, because the entire coating can preferably be applied by means of one and the same apparatus, that is to say all the layers can be applied in one operation. Practical tests have shown that the layers withstand a test of adhesion with the adhesive tape according to DIN 58 196, Part 6.

A further important advantage are the climate-proofness and the UV-proofness. These can be achieved in principle. Thus, the layers withstand climatic tests that are conducted according to ISO 9022-2, and subsequently an adhesion tape test as described above.

The invention can be applied with any type of coating. The layer properties can be controlled by the raw materials used as well as by the operating parameters of the system. The layer properties can vary within wide limits. The intermediate layer is preferably a so-called gradient layer that is composed of a plurality of layers, and in the case of which the layer near the substrate is essentially identical to the substrate, and the layer remote from the substrate is essentially identical to the functional layers.

The invention can also be applied in the case of use of the so-called remote PECVD method or the remote PICVD method. It is known in this case that the plasma space and coating space are separated from one another. Excited and/or dissociated species are conducted from the plasma space into the coating space.

The invention is explained in more detail with the aid of the drawing, in which the following is illustrated in detail:

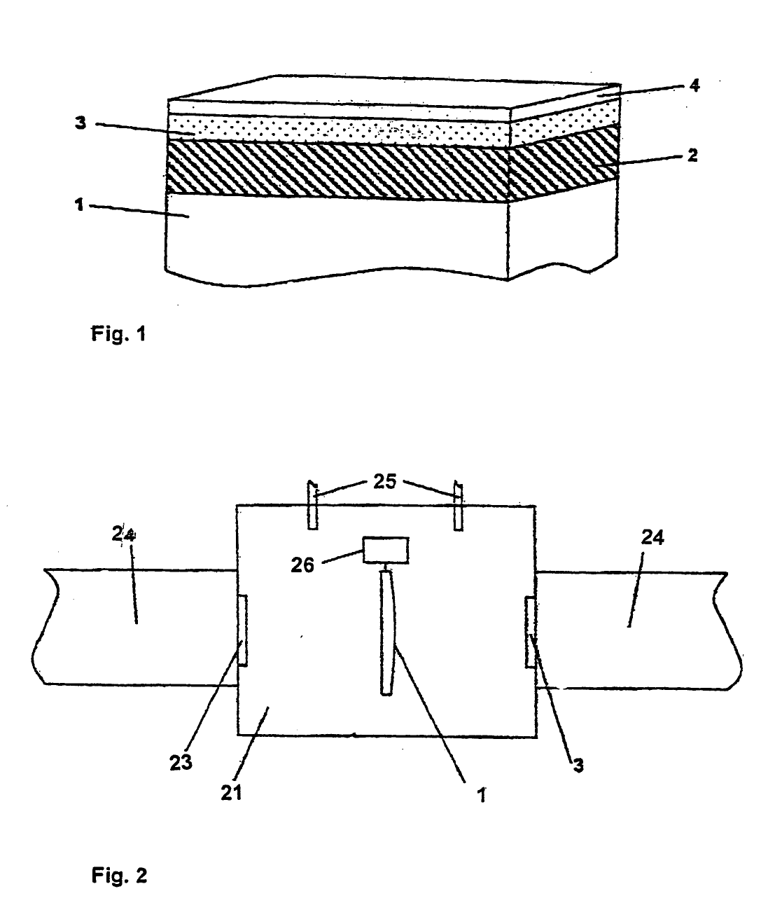

FIG. 1 depicts a perspective sectional illustration of a body according to the invention,

FIG. 2 shows a schematic illustration of a device for coating a substrate,

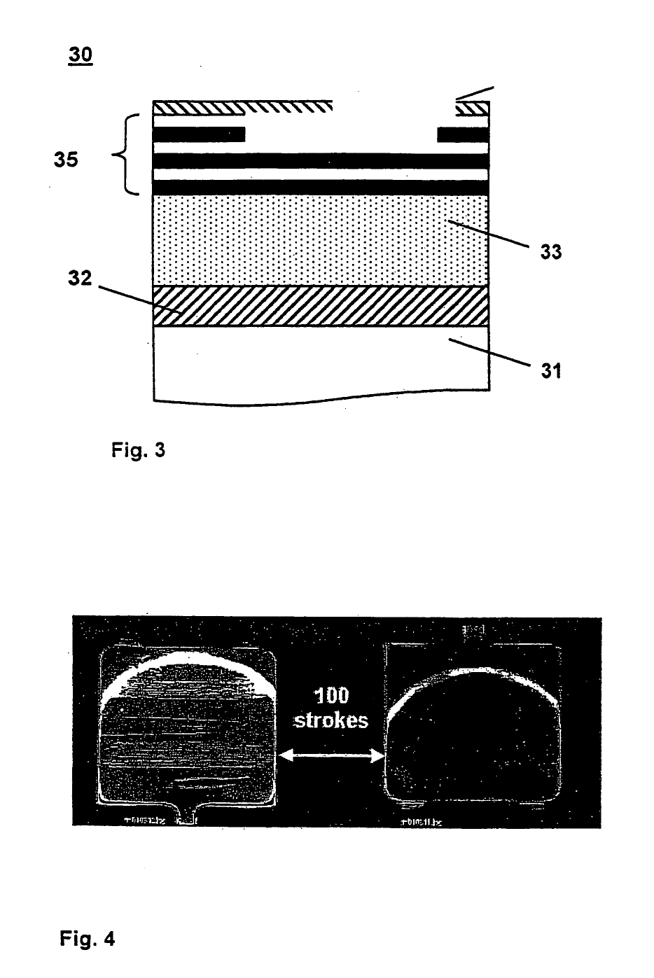

FIG. 3 shows a schematic illustration of a preferred embodiment of the present invention,

FIG. 4 shows a test of the scratch-proofness of a coated substrate according to the invention, and

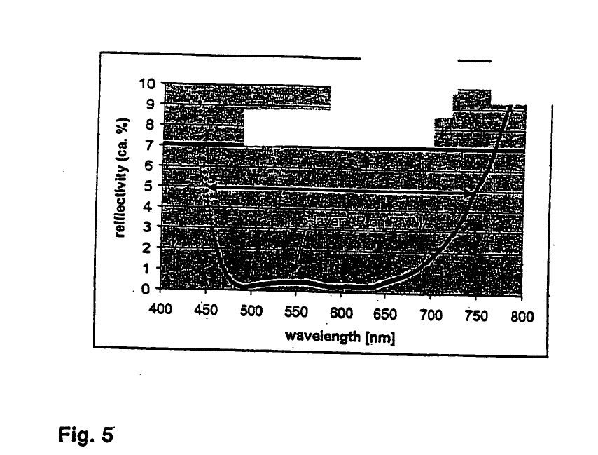

FIG. 5 shows the antireflection properties of a substrate coated according to the invention.

The present invention relates, furthermore, to a coated body that comprises a plastic substrate, an intermediate layer and at least one, preferably more than one functional layer(s), the intermediate layer being arranged between the substrate and the functional layer(s), and it being possible for the coated body to be produced using the method according to the invention.

Bodies of any desired type and shape can be involved in this case. Consideration is given, in particular, to curved bodies or slightly curved bodies, for example spectacle lenses. Flat or approximately flat bodies such as display cover plates, for example in mobile radio units, fixed telephone stations, etc. also come into consideration.

The body according to the invention preferably comprises as plastic one of the abovenamed plastics, of particular preference polymethyl methacrylate (PMMA) as well as derivatives thereof or plastics essentially identical thereto.

FIG. 1 shows an example of a substrate coated according to the invention. A substrate 1 is to be seen in FIG. 1.

Applied to said substrate is an intermediate layer 2. The latter has the function of an adhesion promoter. It is anchored reliably on the substrate, because it has been applied to the substrate in a way according to the invention with minimum energy loading. The intermediate layer 2 can be a so-called gradient layer., built up from a plurality of individual layers of different composition. The individual layer near the substrate 1 is essentially identical to the substrate 1, while the upper layer, remote from the substrate, is essentially identical to a subsequent layer. The subsequent layer is the functional layer 3. The latter executes an optical function, for example. A cover layer 4 forms the termination.

The device shown in FIG. 2 has the following components:

A coating reactor 21 bears the substrate 1. A microwave window 23, a microwave waveguide 24, a gas inlet 25 and a substrate holder 26 are to be seen.

FIG. 3 shows a sectional view of a preferred embodiment of the present invention. An intermediate layer 32 with the function of an adhesion promoter is applied to the substrate 31. There then follows as first functional layer an antiscratching layer 33. Arranged on the latter is an antireflection layer 35 which consists in accordance with this embodiment of alternating layers such as, for example, a total of six SiO₂/TiO₂ layers. A cleaning layer 34 is arranged, finally, as cover layer.

The substrate surface is illustrated in a plane fashion in FIG. 3. By way of example, however, cell phone displays mostly have slightly or more strongly curved surfaces. A uniform coating can be achieved on one or both sides of a substrate by means of the method according to the invention even in the case of such curved surfaces.

A layer structure as shown in FIG. 3 is suitable, in particular, for display covers such as cell phone displays. PMMAs have served as substrate in this example. All the layers were applied successively by means of PICVD methods using the same PICVD apparatus in a single operation. The energy for igniting the plasma in the chamber was introduced in the form of microwaves at a frequency of typically 2.45 GHz. The different layers were yielded from different method conditions and/or precursor compounds fed into the chamber, if appropriate in combination with oxygen and/or further carrier or reaction gases. For example, the adhesion promoter layer is still rich in carbon and essentially identical to the organic PMMA substrate. This layer is flexible owing to its polymeric nature. It was found, surprisingly, that by means of the method according to the invention the adhesion promoter layer also adheres unexpectedly well to a PMMA substrate that is otherwise difficult to coat, and in this case at the same time no damage occurs to the surface of the substrate. The antiscratching layer 33 applied thereto is a coating with a lower carbon content, which is distinguished by a greater hardness. The same organosilicon starting compound such as, for example, hexamethyldisiloxane (HMDSO), can be used to produce these layers 32 and 33, oxygen also being introduced into the system to produce an inorganic coating. Depending on the method conditions, a pure inorganic quartz coating is produced by complete oxidation of the hydrocarbon component of HMDSO to form carbon dioxide and water, or a carbon-rich organic polymer compound is formed by incomplete oxidation. In this case, the transition from such an intermediate layer to the antiscratching layer can also be configured as a gradient layer by gradual change to the method conditions. A precursor compound such as TiCl₄ is introduced into the system together with oxygen in order to produce a TiO₂ layer. The gas contained in the chamber after the plasma discharge is preferably changed after each impulse such that no gradient is produced in the plasma itself. It is possible thereby to achieve a very uniform coating.

The multilayer system thus obtained is climate-proof and withstood a test of adhesion, as previously described.

It was possible to operate at very low temperatures even at room temperature because of the pulsed method, and so no damage occurred to the substrate surface or the interface between substrate and intermediate layer. Furthermore, it was possible to achieve a closed and very homogeneous coating.

FIG. 4 shows photographs of a PMMA substrate (right-hand image) coated according to the invention in comparison with a non-coated PMMA substrate (left-hand image). The substrates were subjected to a scratching test, the surface being rubbed 100 times in accordance with DIN 58196, Part 5, with a so-called cheesecloth and a bearing force of 450 g. Traces of scratching are clearly to be seen on the non-coated substrate, whereas the substrate coated according to the invention exhibits an undamaged surface.

FIG. 5 shows the reflection-reducing properties of an antireflection layer, contained as in the previous example, on a PMMA surface. Whereas uncoated PMMA has a base line reflection of approximately 7%, the reflection of a substrate coated according to the invention is substantially lowered in the region of visible light.

The present invention also relates to a transparent coated substrate that contains an organic polymeric substrate and, at least on one side of the substrate, at least one dielectric layer applied by means of CVD.

The polymeric substrate is preferably coated by means of a pulsed, plasma-assisted CVD method (PICVD). The plasma is produced in this case by radiation with microwaves. The method offers the following advantages:

(i) The heat exposure of the polymer substrates during coating can be kept very slight in conjunction with high quality and adhesion of the deposited layers by suitable selection of the impulse cycles and the impulse power inserted into the plasma.

(ii) In addition to the parameters of the plasma pulsing, the method offers a range of further degrees of process freedom with the aid of which the properties of the successively applied layers can be influenced specifically and optimized with regard to the requirements placed on the stability.

A preferred refinement of the invention is a transparent coated substrate, the organic polymeric substrate including at least one of the polymers such as polycarbonate, polyetherimide, polymethyl methacrylate, cyclic olefins or olefin copolymers or mixtures and blends thereof or at least one thermoplastic amorphous resin.

Use may be made in this case of the following commercially available polymers: polycarbonate (Makrolon®), cycloolefin copolymers (Topas® or Zeonex®), polyetherimide (Ultem®) or polyether sulfone (Ultrason®).

A further preferred refinement of the invention is a transparent coated substrate, at least one layer of at least one metal oxide being applied to the substrate by means of CVD. The metal oxides are preferably oxides of the metals Si, Ti, Ta or Nb. It is particularly preferred for the metal oxides to be SiO₂, TiO₂, Ta₂O₅ or Nb₂O₅. Very good results are obtained with these metal oxides in the case of layer adhesion.

A further preferred refinement of the invention is a transparent coated substrate, the layer on the substrate optionally including an intermediate layer and an antireflection layer thereupon, and optionally a cover layer thereupon, and the intermediate layer, antireflection layer and cover layer include at least one layer. All these layers are advantageously applied in one method.

A further preferred refinement of the invention is a transparent coated substrate, the thickness of the intermediate layer being from up to 10 μm, that of the antireflection layer being from 50 nm to 1 μm, and that of the cover layer being from 0 to 1 μm. Very good results are obtained with these layer thicknesses in the case of layer adhesion.

The transparent coated substrate according to the invention has a planar, plano-convex, biconvex, plano-concave, biconcave, concave-convex or any desired aspheric shape.

According to the invention, a method is provided for producing a transparently coated substrate, optionally an intermediate layer and, thereupon, an antireflection layer and, thereupon optionally a cover layer being applied to the transparent substrate by means of CVD, preferably by means of PICVD or PECVD.

The use of the transparent coated substrate as optical lens is provided according to the invention. Furthermore, the use of the transparent coated substrate as a constituent in illuminating or imaging optical systems is provided according to the invention. The optical systems according to the invention have very good optical properties and satisfy the requirements placed on turbidity and layer adhesion.

This embodiment of the present invention is explained in more detail below with the aid of a further example.

A lens made from Topas 6015® material was introduced into a coating reactor with a special sample holder. After evacuation to a pressure of the order of magnitude of 1 mbar, a brief plasma pretreatment followed for the purpose of activating the substrate surface. Subsequently, there was deposited on the lens an intermediate layer and, thereupon, an antireflection layer package consisting of 4 layers with SiO₂ as lowrefractive-index layer material and TiO₂ as high-refractiveindex layer material. In this case, the pulse duty factor of the plasma pulsing was approximately 5%. The substrate temperature during coating was 30° C. In addition to the measurement of their spectral transmission, the coated lenses were subjected to the following rests:

(i) tape test (adhesive tape test),

(ii) slow change in temperature between 20° C. and 85° C., for a residence time of 2.5 h (5 cycles),

(iii) constant climate, 16 h at 55° C. and 100% relative humidity.

No delaminations of the layer package occurred after the tape test. Likewise, no delaminations were to be seen after the test with the change in temperature and the constant climate test. The coated lens exhibited a constant brilliance. Defect features of the coating such as, for example, cracks or turbidity were not observed. Consequently, measurements of the optical spectral properties yielded no change after tests with a change in temperature and a constant climate.

1. A method for coating a plastic substrate having at least one functional layer and at least one intermediate layer located between the functional layer(s) and the substrate, comprising the following method steps:
(1) applying the intermediate layer to the substrate by means of a PECVD method, the application being performed in conjunction with minimum energy loading of the substrate, and
(2) applying at least one functional layer.

2. The method as claimed in claim 1, in which the intermediate layer and/or at least one functional layer are applied by means of a PICVD method.

3. The method as claimed in claim 1 or 2, in which at least two functional layers are applied to the intermediate layer.

4. The method as claimed in claim 2 or 3, in which the total duration of the plasma action is at least 1/1 000 of the action-free time interval between two plasma impulses and is at most equal to said time interval.

5. The method as claimed in claim 2, 3 or 4, in which the action impulse of the plasma application lasts between 0.1 and 10 ms.

6. The method as claimed in one of the preceding claims, in which there is coated a plastic substrate that comprises polymethyl methacrylate (PMMA) or a derivative thereof or a plastic essentially identical thereto.

7. The method as claimed in one of the preceding claims, in which a coating rate of more than 10 nm/min is used in the case of the plasma action.

8. A device for coating a plastic substrate with at least one functional layer as well as an intermediate layer lying between the substrate and the functional layer(s), which comprises a PECVD apparatus for applying the intermediate layer to the substrate in conjunction with minimum energy loading of the surface of the substrate.

9. The device as claimed in claim 8, which comprises a PICVD apparatus for applying the intermediate layer to the substrate in conjunction with minimum energy loading of the surface of the substrate.

10. A coated body comprising a plastic substrate, an intermediate layer and at least one functional layer, the intermediate layer being arranged between the substrate and the functional layer(s), and which can be produced using a method as claimed in one of claims 1 to 7.

11. The coated body as claimed in claim 10, in which the substrate comprises PMMA or a derivative thereof or a plastic essentially identical thereto.

12. The use of a method as claimed in one of claims 1 to 7 for producing display cover plates.

13. The use of a method as claimed in one of claims 1 to 7 for producing optical lenses.

14. The use as claimed in claim 13 as a constituent in illuminating or imaging optical systems.
